(19) United States
(12) Patent Application Publication
(10) Pub. No.: US 2009/0213548 A1
(43) Pub. Date: Aug. 27, 2009

(54) THERMALLY CONDUCTIVE PERIODICALLY STRUCTURED GAP FILLERS AND METHOD FOR UTILIZING SAME

(76) Inventors: Roger S. Kempers, Dublin (IE); Richard T. Lagrotta, Livingston, NJ (US); Walter J. Picot, Boonton Township, NJ (US); Joseph A. Borowiec, Brooklyn, NY (US); Shankar Krishnan, Dublin (IE)

Correspondence Address: WALL & TONG, LLP/;ALCATEL-LUCENT USA INC., 595 SHREWSBURY AVENUE, SHREWSBURY, NJ, 07702, US

(21) Appl. No.: 12/034,734

(22) Filed: Feb. 21, 2008

(51) Int. Cl. H05K 7/20

(52) U.S. Cl. 361/704

(57) ABSTRACT

A method for conducting heat between a heat source and a heat sink includes disposing under a compressive force therebetween a plurality of thermally conducting unit cell structures that mechanically cooperate to form thereby a body structure having an aggregate thermal conductivity that changes in response to a compressive force exerted thereon, wherein an amount of said plurality of thermally conducting unit cell structures disposed therein is selectable to affect thereby a desired aggregate thermal conductivity in response to the compressive force.

### FIELD OF THE INVENTION

The invention relates to thermal management and, more specifically, to providing efficient thermal conduction between heat generating devices and respective cooling structures to assure sufficient cooling of the devices.

### BACKGROUND

In thermal interfacing applications such as electronic cooling, heat exchangers and the like, there are often situations in which a physical gap between a heat generating device (e.g., a power dissipating electronic component) and a corresponding cooling structure (e.g., a heatsink) must be efficiently bridged to keep the temperature of the device within operational limits. In many such cases, devices rely on thermal conduction to the chassis to which they are attached to provide adequate cooling. Due to manufacturing variations and limitations, the size of these gaps can be on the order of 1 to 10 mm. Without a suitable interstitial material, the heat transfer from the device to the cooling structure is provided by some combination of conduction and convection, depending on the quality and consistency of the thermal path established. The thermal path may comprise, for example, convection in the air gap or conduction through the component lead frames to the printed circuit board. Often, these mechanisms alone are not sufficient to cool the device.

### SUMMARY

Various deficiencies of the prior art are addressed by embodiments including a method for conducting heat between a heat source and a heat sink, comprising disposing between the heat source and heat sink a plurality of thermally conducting unit cell structures that mechanically cooperate to form thereby a body structure having an aggregate thermal conductivity that changes in response to a compressive force exerted thereon; wherein an amount of said plurality of thermally conducting unit cell structures disposed therein is selectable to affect thereby a desired aggregate thermal conductivity in response to the compressive force.

### BRIEF DESCRIPTION OF THE DRAWINGS

The teachings of the present invention can be readily understood by considering the following detailed description in conjunction with the accompanying drawings, in which:

FIG. 1A depicts a thermally conductive elastomeric gap filler;

FIG. 1B depicts a compressed thermally conductive elastomeric gap filler;

FIG. 2A depicts a body centered cubic structure;

FIG. 2B depicts a face centered cubic structure;

FIG. 2C depicts a hybrid cubic structure;

FIG. 3 depicts a gap filler compressed between a heat source and a heat sink;

FIG. 4 graphically depicts stress as a function of strain to provide an exemplary compressive stress-strain profile of a gap filler;

FIG. 5 graphically depicts thermal conductivity as a function of strain to provide an exemplary thermal conductivity profile of a gap filler;

FIG. 6 depicts an exemplary embodiment of a gap filler such as provided in FIG. 2, wherein a portion of a cellular structure is are intentionally modified; and

FIG. 7 depicts a two components pressed together by force with a gap filler and dielectric material disposed between the two.

To facilitate understanding, identical reference numerals have been used, where possible, to designate identical elements that are common to the figures.

### DETAILED DESCRIPTION

Various embodiments will be primarily described within the context of a thermally conductive compliant metal gap filler, however, those skilled in the art and informed by the teachings herein will realize that other embodiments can also include electrical bonding, insulating, and multiple other applications. Moreover, while application of the thermally conductive compliant metal gap filler is generally discussed within the context of cooling electronic or electro-optic components, the material and methods of utilization are also applicable to heat exchangers, boilers and/or other industrial equipment. These and other modifications are contemplated by the inventors.

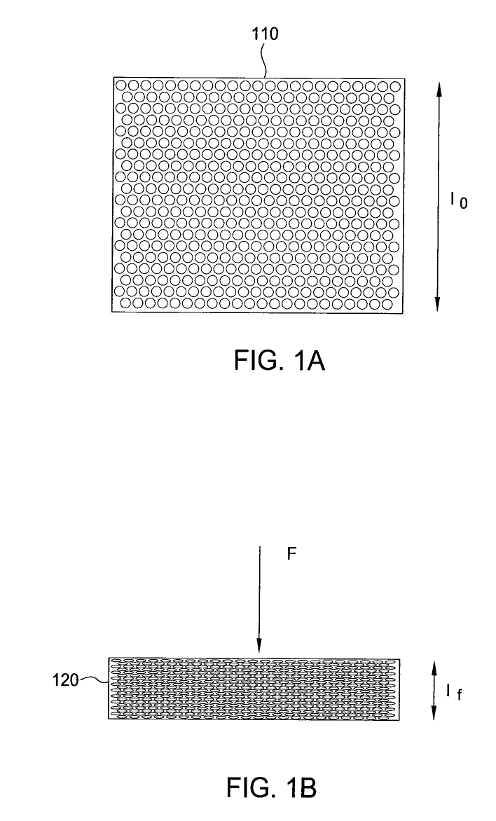

FIG. 1A depicts a thermally conductive elastomeric gap filler 110 of height I₀ per one embodiment. Thermally conductive gap filler 110 comprises a plurality of thermally conducting unit cell structures mechanically cooperating to form a body structure that changes in response to a compressive force exerted thereon. In various exemplary embodiments, gap filler 110 is characterized as having a porous periodically arranged cellular (unit cell) structure which is constructed of a material having a relatively high conductivity such that it is suited to be placed in compression between a heat source and heat sink to thereby enhance thermal conductivity between the two. Gap filler 110 can be constructed of one or more relatively soft metals such as copper, aluminum, gold and silver, as well as graphite or any other suitable material (including composites) depending upon application. In one embodiment, a gap between heat source and sink components is filled using a determined amount or portion of the plurality of thermally conducting unit cell structures comprising the body structure. Specifically, the amount of material used is selectable so as to thereby produce/affect a desired aggregate thermal conductivity in response to a particular (e.g. expected or specified) compressive force exerted thereon.

FIG. 1B depicts a compressed thermally conductive gap filler 120, obtained from compressing thermally conductive gap filler 110 to a height of I_{f}, according to one embodiment. As the thermally conductive gap filler 110 is compressed, its thermal conductivity increases. This is accomplished in two ways: (1) the porosity of the structure decreases (i.e., more internal metal to metal contact with less cell “filler” material such as air), resulting in an increased effective thermal conductivity of the body structure; and (2) the overall thickness of the structure decreases. As the thickness of compressed gap filler 120 (gap filler 110) progressively decreases to a limiting case of porosity becoming zero, its thermal conductivity k approaches that of a solid material. Thus, the inventors have determined that the thermal conductivity k may be controlled by controlling the compression forces exerted upon the material.

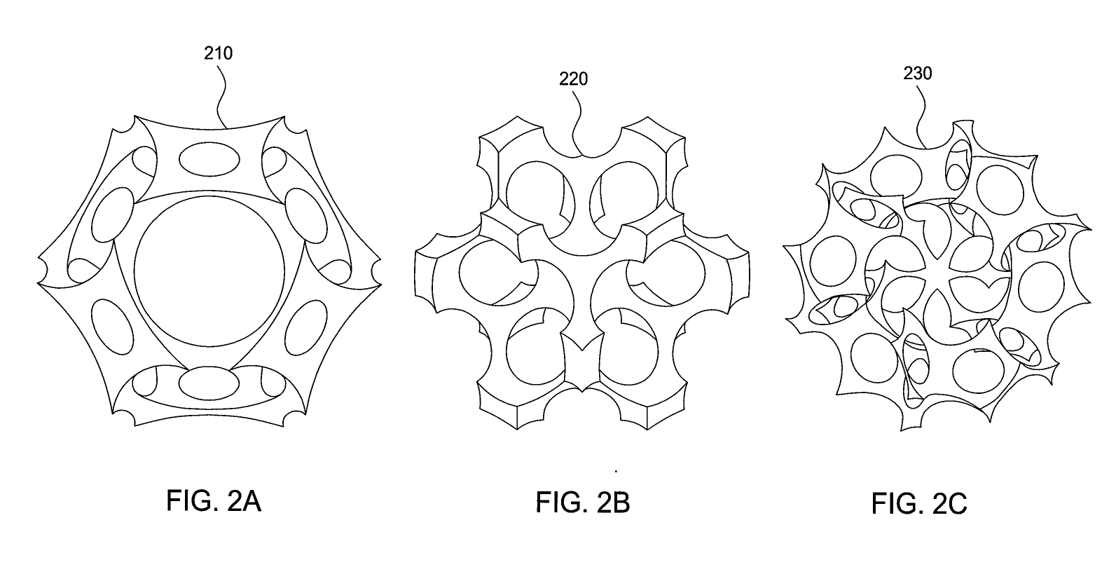

In various embodiments, structural features of the periodically arranged unit cells comprising the gap filler are adapted (i.e. selectable) to achieve an optimized balance between a compressive pressure required to adequately deform the gap filler (body structure), and its compressed porosity and effective thermal conductivity. FIGS. 2A, 2B and 2C depict exemplary unit cell structures with features that may be advantageously tailored to achieve desired mechanical and thermal properties of gap fillers for specific applications. Specifically, FIG. 2A depicts a body centered cubic structure 210; FIG. 2B depicts a face centered cubic structure 220; and FIG. 2C depicts a hybrid cubic structure 230. Structures 210, 220, and 230 are periodically structured open-porous segments suitable for use as the unit cell structures comprising the body structure of thermally conductive elastomeric gap filler 110 discussed in reference to FIG. 1A. By altering aspects of the shape and/or material composition of structures 210, 220 and 230, these structures are optionally adapted to integrate multiple features into the gap filler, such as high compliance for lower compressive strength, and/or enhanced effective thermal path for heat flow between components as examples. It will be appreciated by those skilled in the art and informed by the teachings herein that other and further structures in addition to structures 210, 220 and 230 can be utilized while still remaining in conformance with envisioned embodiments. Those optionally include any suitable periodic structure as mentioned, as well as any suitable non-periodic, non-symmetrical, closed geometry (closed pore), or open geometry (open pore) structure. In general, any structure can be utilized wherein its dimensions (shape) and/or composition (material) can be adapted to perform a desired function or combinations thereof.

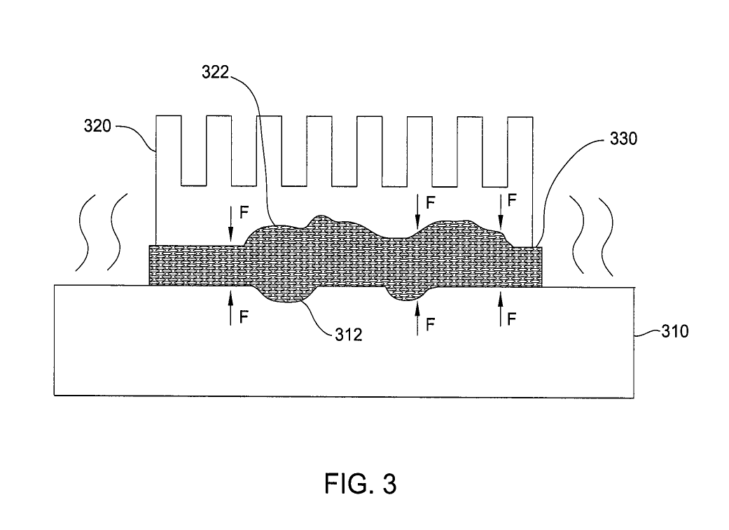

In one embodiment, a gap filler such as thermally conductive gap filler 110 is comprised of a plurality of mechanically cooperating unit cell structures such as structures 210, 220 and/or 230 is disposed between a heat source and heat sink each having surface asperities. The heat source and heat sink are drawn closer together, compressing the gap filler and causing it to conform to and/or fills the asperities in the respective surfaces. An example of this embodiment is depicted in FIG. 3. FIG. 3 depicts a heat source 310 having heat source surface voids (asperities) 312; heat sink 320 having heat sink surface voids (asperities) 322; and conforming gap filler 330. Conforming gap filler 330 is placed between heat source 310 and heat sink 320, and a force F applied to the heat source 310 and heat sink 320. As heat source 310 and heat sink 320 are pressed together by force F, conforming gap filler 330 is compressed. As conforming gap filler 330 is compressed, its elastomeric properties cause it to fill heat source surface voids 312 and heat sink surface voids 322 as mentioned above, thereby optimizing thermal conductivity between the two, which would have been compromised by the voids had conforming gap filler 330 not been provided.

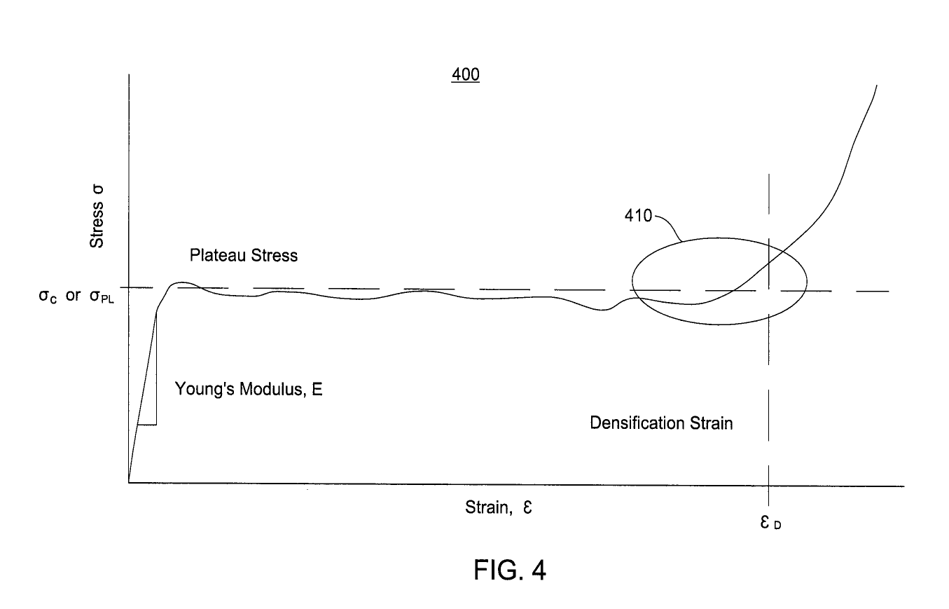

FIG. 4 graphically depicts stress as a function of strain to provide an exemplary compressive stress-strain profile of a gap filler. Specifically, FIG. 4 graphically depicts an exemplary compressive stress-strain profile 410 for a metal gap filler such as gap filler 110 and/or conforming gap filler 330, according to one embodiment. At a relatively low stress, the gap filler yields plastically in proportion to Young's Modulus (E) until the stress-strain curve (stress-strain profile 400) reaches a relatively constant plateau stress value σ_{PL}. Typically, open cell gap fillers have a long well defined σ_{PL} duration within which the cellular structures comprising the gap filler collapse. The plateau σ_{PL} continues to a densification strain ε_{D}, beyond which the porosity (void fraction) drops sharply and the gap filler compacts approaching a fully dense material. The point at which ε_{D} is reached is depicted on stress-strain profile 400. In certain embodiments, the point on or about where ε_{D} is reached is considered an ideal operating range for the gap filler, and is accordingly noted as ideal operating range 410 on stress-strain profile 400, wherein thermal conductivity reaches its maximum point within the range of σ_{PL}. It should be emphasized however, that ideal operating range 410 is not necessarily the ideal operating range for all embodiments, and the gap filler can be utilized in any suitable degree of compression befitting the application it is being implemented in.

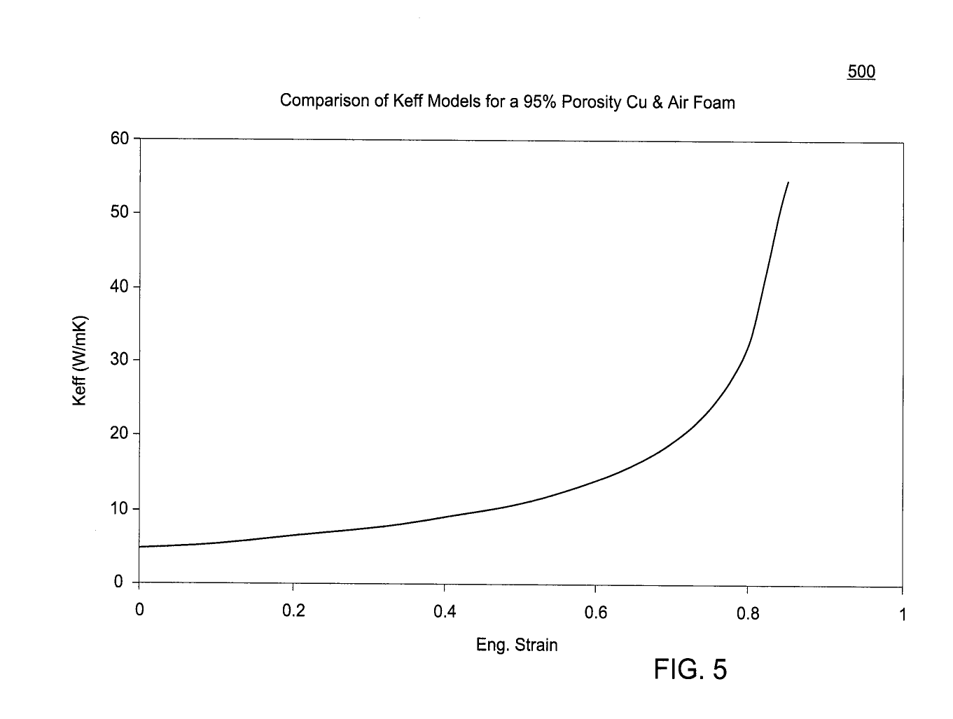

In various embodiments, increased strain on the gap filler is proportional to increase of its thermal conductivity. FIG. 5 graphically depicts thermal conductivity as a function of strain to provide an exemplary thermal conductivity profile of a gap filler. Specifically, FIG. 5 depicts strain vs. thermal conductivity profile 500, showing a typical example of thermal conductivity increasing as strain (from an applied stress) in a material such as gap filler 110 and/or conforming gap filler 330 increases. In general (but not necessarily), for a metal gap filler to function as an effective thermal gap filler, it will in an exemplary embodiment have a low compressive strength (yield strength) and a high relative thermal conductivity resulting in an ideal operating condition near ε_{D}. Pure metals such as copper, aluminum, gold and silver have desirable attributes for such embodiments because of their low yield stress and high thermal conductivity.

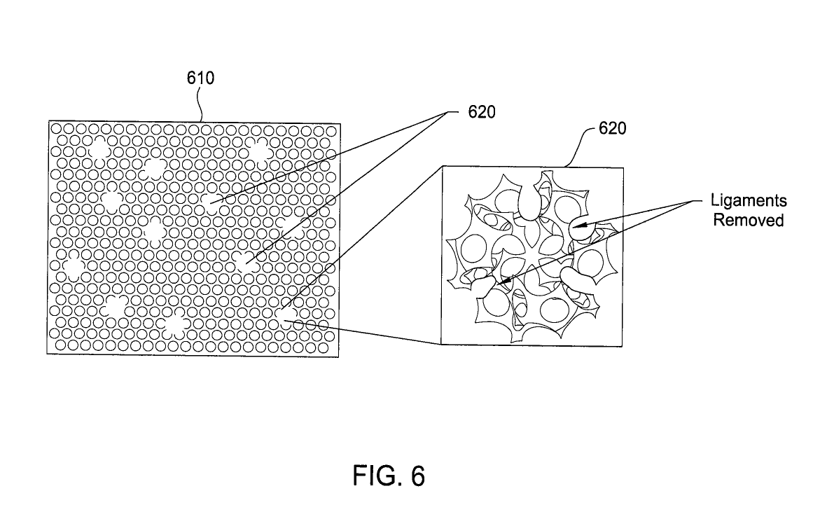

In further embodiments, a portion of the plurality of thermally conducting unit cell structures mechanically cooperating to form a body structure such as gap fillers 110 and/or 330, include inconsistencies (e.g. defects) in the unit cell structure. The inconsistencies are intentionally provided in the unit cell structure to specifically affect how the gap filler collapses under a given applied pressure, and its thermal conductivity profile changes under an increasing compression (strain). FIG. 6 depicts an example of such an embodiment, wherein a hybrid gap filler 610 is partially or wholly comprised of modified unit cells 620. Modified unit cells 620 may as examples be unit cell structures such as structures 210, 220 and 230 having ligaments or other sections of their geometry removed or modified in some fashion intended to affect the thermal and mechanical properties of the gap filler in a desired manner. Such an embodiment may be necessary, for example, to achieve a specific stress-strain or thermal conductivity profile such as stress-strain profile 400 or thermal conductivity profile 500, or others. It may be desirable in particular embodiments to strategically place modified unit cells 620 within a gap filler body structure so as to intentionally produce a non uniform stress-strain and thermal conductivity profile, and/or implement specific properties in different areas in the body structure, as applications warrant. Examples where such embodiments might utilized could be instances where surface features such as heat source surface void 312 and heat sink surface void 322 of bodies between which the gap filler is to be compressed are known. In those instances, modified unit cells 620 may be adapted and placed how/wherever necessary to achieve a desired function.

In various embodiments, a body structure such as gap filler 110 and/or conforming gap structure 330 is adapted to perform electrical bonding when disposed between two bodies in compression. In a similar embodiment, the body structure could also be adapted to serve as an Electromagnetic Interference (EMI) shielding gasket/apparatus when the unit cell structures of the gap filler are sized or compressed sufficiently enough such that any remaining void in the unit cells are much smaller than the wavelength of an incident electromagnetic field desired to be shielded. In such embodiments (electrical bonding, EMI shielding, etc.) the unit cell structures of the gap filler are constructed of materials with having a high electrical conductivity.

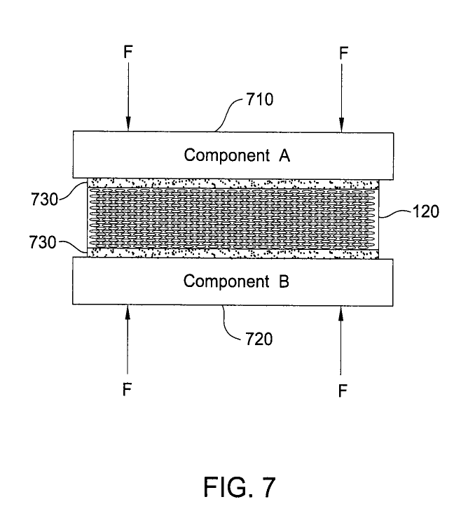

In yet another embodiment, a body structure such as gap filler 110 and/or conforming gap structure 330 is adapted to serve as an electrical insulator when disposed between two components in compression. FIG. 7 depicts a component A 700 and a component B 720 pressed together by force F, with compressed gap filler 120 and a dielectric material 730 disposed between the two. Dielectric material 720 is comprised of a material having a high thermal conductivity but low electrical conductivity. An example of such a material could be a mica (Phlogopite, Biotite, Zinnwaldite, Lepidolite, etc.), or any suitable material or materials possessing the desired properties.

In various other embodiments, thermally conductive grease is optionally permeated throughout the gap filler examples mentioned herein (gap filler 110, conforming gap filler 330, etc.) to elevate thermal conductivity of the body structures, by filling any voids left by uncompressed and/or not fully compressed unit cells. The thermally conductive grease can either be electrically conductive or a dielectric depending upon whether electric bonding or insulating functionality is desired for the gap filler. In similar embodiments an adhesive that is either electrically conductive or a dielectric can be permeated throughout the gap filler to aid in bonding the gap filler to whatever components its is disposed/compressed between.

Yet another exemplary embodiment can be construed as a method for conducting heat between a heat source and a heat sink, comprising disposing between the heat source and heat sink a plurality of thermally conducting unit cell structures that mechanically cooperate to form thereby a body structure having an aggregate thermal conductivity that changes in response to a compressive force exerted thereon; wherein an amount of said plurality of thermally conducting unit cell structures disposed therein is selectable to affect thereby a desired aggregate thermal conductivity in response to the compressive force.

While the foregoing is directed to various embodiments of the present invention, other and further embodiments of the invention may be devised without departing from the basic scope thereof. As such, the appropriate scope of the invention is to be determined according to the claims, which follow.

What is claimed is:

1. A method for conducting heat between a heat source and a heat sink, comprising:
disposing between the heat source and heat sink a plurality of thermally conducting unit cell structures that mechanically cooperate to form thereby a body structure having an aggregate thermal conductivity that changes in response to a compressive force exerted thereon;
wherein an amount of said plurality of thermally conducting unit cell structures disposed therein is selectable to affect thereby a desired aggregate thermal conductivity in response to the compressive force.

2. The method of claim 1, further comprising selecting a shape for the amount of said plurality of thermally conducting unit cell structures to affect the mechanical properties of at least a portion of the body structure.

3. The method of claim 1, further comprising selecting a shape for the amount of said plurality of thermally conducting unit cell structures to affect the thermal conduction properties of at least a portion of the body structure.

4. The method of claim 1, further comprising permeating the body structure with thermally conductive grease.

5. The method of claim 1, further comprising placing a dielectric material between the heat source and plurality of thermally conducting unit cell structures.

6. The method of claim 1, further comprising placing a dielectric material between the heat sink and plurality of thermally conducting unit cell structures.

7. The method of claim 1, wherein the thermally conducting unit cell structures are comprised of metal.

8. The method of claim 1, wherein the thermally conducting unit cell structures are comprised of graphite.

9. The method of claim 1, wherein the thermally conducting unit cell structures are comprised of a composite.

10. The method of claim 1, wherein the thermally conducting unit cell structures comprise an open pore geometry

11. The method of claim 1, wherein the thermally conducting unit cell structures comprise a closed pore geometry

12. The method of claim 1, further comprising permeating the body structure with dielectric grease.

13. The method of claim 1, further comprising permeating the body structure with an adhesive.

14. The method of claim 10, wherein the open pore geometry is a body centered cubic.

15. The method of claim 10, wherein the open pore geometry is a face centered cubic.

16. The method of claim 1, wherein the heat source comprises an electronic component.

17. The method of claim 1, wherein the heat source comprises an industrial component.

18. An elastomeric gap filler, comprising:
a plurality of thermally conducting unit cell structures, mechanically cooperating to form thereby a body structure having an aggregate thermal conductivity that changes in response to a compressive force exerted thereon;
wherein an amount of said plurality of thermally conducting unit cell structures disposed therein is selectable to affect thereby a desired aggregate thermal conductivity in response to the compressive force.

19. An elastomeric gap filler, comprising:
a plurality of thermally conducting unit cell structures, mechanically cooperating to form thereby a body structure having an aggregate thermal conductivity, wherein an amount of said plurality of thermally conducting unit cell structures disposed therein is selectable to affect thereby a desired aggregate thermal conductivity.

20. The elastomeric gap filler of claim 19, wherein the amount of said plurality of thermally conducting unit cell structures is selectable to fill a gap of predetermined dimensions.

21. The elastomeric gap filler of claim 20, wherein the elastomeric gap filler is compressible, and compression thereof increases the aggregate thermal conductivity.

22. The elastomeric gap filler of claim 20, wherein the elastomeric gap filler is compressible, and compression thereof abets in completely filling the gap.

23. The method of claim 1, wherein the body structure is disposed to perform Electromagnetic Interference (EMI) shielding.

24. The elastomeric gap filler of claim 19, wherein the gap filler is disposed to perform Electromagnetic Interference (EMI) shielding.
